(19) United States
(12) Patent Application Publication
(10) Pub. No.: US 2024/0145365 A1
(43) Pub. Date: May 2, 2024

(54) ELECTRONIC INTERCONNECT AND METHOD OF FORMING THE SAME

(71) Applicant: Intel Corporation, Santa Clara, CA (US)

(72) Inventors: Bok Eng CHEAH, Gelugor (MY); Seok Ling LIM, Kulim Kedah (MY); Jenny Shio Yin ONG, Bayan Lepas (MY); Kooi Chi OOI, Gelugor (MY); Jackson Chung Peng KONG, Tanjung Tokong (MY)

(21) Appl. No.: 18/050,519

(22) Filed: Oct. 28, 2022

(51) Int. Cl. H01L 23/498; H01L 21/48

(52) U.S. Cl. CPC H01L 23/49822; H01L 21/4857; H01L 23/49811; H01L 23/49833

(57) ABSTRACT

A device is provided, including a dielectric layer, a plurality of first conductive segments within the dielectric layer and spaced apart from each other by respective first spacings, and a plurality of second conductive segments within the dielectric layer and spaced apart from each other by respective second spacings. The plurality of second conductive segments may be over and spaced apart from the plurality of first conductive segments by the dielectric layer. A respective one of the first conductive segments may at least partially extend across a corresponding one of the second spacings, and a respective one of the second conductive segments may at least partially extend across a corresponding one of the first spacings.

### BACKGROUND

In conventional electronic package design, there have been challenges of input/output (I/O) interconnect density scaling, e.g., electrical interconnects between a package and a printed circuit board (PCB), for improved performance and functionality. A semiconductor package with liquid metal based second level interconnects (SLI) may provide improved electrical and/or mechanical performance. Nevertheless, increased package and/or PCB footprint is unavoidable with the up-scaling of I/O count and/or device functionality that may inhibit device form-factor miniaturization.

Current solutions to cope with the increased device I/O density requirements may include direct chip attach (DCA) approach wherein a silicon device is directly mounted on the PCB without the package substrate or down-scaling of the liquid metal interconnect pitch geometry. This may affect device reliability, e.g., solder joint reliability and/or manufacturability due to the interconnect geometry miniaturization.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1 shows a cross-sectional view of a device according to an aspect of the present disclosure.

FIG. 2 shows a cross-sectional view of a device according to another aspect of the present disclosure.

FIG. 3 shows a cross-sectional view of a device according to a further aspect of the present disclosure.

FIG. 4 shows a flow chart illustrating a method of forming a device according to an aspect of the present disclosure.

FIGS. 5A through 5H show cross-sectional views directed to an exemplary process flow for a method of making a device according to an aspect of the present disclosure.

FIG. 6 shows an illustration of a computing device that includes a semiconductor device according to a further aspect of the present disclosure.

### DETAILED DESCRIPTION

The following detailed description refers to the accompanying drawings that show, by way of illustration, specific details and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects can be combined with one or more other aspects to form new aspects.

The present disclosure introduces an electronic interconnect for an electronic assembly, e.g., a high-density liquid metal interconnect coupling a package substrate to a printed circuit board (PCB).

Advantages of the present disclosure may include device miniaturization through increased second level interconnect input/output (I/O) density. A staggered liquid metal interconnect stack according to various aspects of the present disclosure may allow higher I/O density without resorting to increased package and PCB form-factor.

Another advantage of the present disclosure may include enhanced electrical performance by allowing additional ground (Vss) shielding between high-speed signal pins, thus reducing crosstalk noises. Improved power integrity (PI) performance may be achieved through tightly coupled power-ground (Vcc-Vss) pins, thus reducing power loop inductance path.

Further advantages of the present disclosure may include enhanced multi-platform compatibility for a single central processing unit or system-on-chip (CPU/SOC) package design configuration. For example, a single CPU/SOC package design with superset features and pitch geometry of 0.4 mm may be configured in a first PCB design such as a Type-4 high density interconnect (HDI) PCB for high performance product applications, or configured in a second PCB design such as a Type-3 low-cost PCB (with larger pitch geometry and/or reduced features) for entry product applications. This may allow simplification of CPU/SOC package configurations for cross-segment applications, hence achieving product time-to-market improvements.

In all aspects, the present disclosure generally relates to a device that may include a dielectric layer, a plurality of first conductive segments within the dielectric layer and spaced apart from each other by respective first spacings, and a plurality of second conductive segments within the dielectric layer and spaced apart from each other by respective second spacings. The plurality of second conductive segments may be over and spaced apart from the plurality of first conductive segments by the dielectric layer. A respective one of the first conductive segments may at least partially extend across a corresponding one of the second spacings, and a respective one of the second conductive segments may at least partially extend across a corresponding one of the first spacings.

The present disclosure generally relates to a method of forming a device. The method may include forming a plurality of first conductive segments within a dielectric layer, wherein the plurality of first conductive segments may be spaced apart from each other by respective first spacings; and forming a plurality of second conductive segments within the dielectric layer and over the plurality of first conductive segments, wherein the plurality of second conductive segments may be spaced apart from each other by respective second spacings and spaced apart from the plurality of first conductive segments by the dielectric layer; wherein a respective one of the first conductive segments may at least partially extend across a corresponding one of the second spacings, and a respective one of the second conductive segments may at least partially extend across a corresponding one of the first spacings.

The present disclosure generally relates to an electronic package. The electronic package may include a dielectric layer; a plurality of first conductive segments within the dielectric layer and spaced apart from each other by respective first spacings; a plurality of second conductive segments within the dielectric layer and spaced apart from each other by respective second spacings, wherein the plurality of second conductive segments may be over and spaced apart from the plurality of first conductive segments by the dielectric layer, and wherein a respective one of the first conductive segments may at least partially extend across a corresponding one of the second spacings, and a respective one of the second conductive segments may at least partially extend across a corresponding one of the first spacings; a package substrate on a top surface of the dielectric layer, wherein the package substrate may include a plurality of first package contacts having a first length and a plurality of second package contacts having a second length greater than the first length, wherein a respective one of the plurality of first package contacts may be configured to extend into a corresponding one of the plurality of second conductive segments, and wherein a respective one of the plurality of second package contacts may be configured to extend into a corresponding one of the plurality of first conductive segments through a corresponding one of the second spacings; and at least one chip coupled to a top surface of the package substrate.

The present disclosure generally relates to a computing device. The computing device may include an interconnect structure including a dielectric layer, a plurality of first conductive segments within the dielectric layer and spaced apart from each other by respective first spacings, and a plurality of second conductive segments within the dielectric layer and spaced apart from each other by respective second spacings, wherein the plurality of second conductive segments may be over and spaced apart from the plurality of first conductive segments by the dielectric layer, and wherein a respective one of the first conductive segments may at least partially extend across a corresponding one of the second spacings, and a respective one of the second conductive segments may at least partially extend across a corresponding one of the first spacings. The computing device may further include a package substrate on a top surface of the dielectric layer, wherein the package substrate may include a plurality of first package contacts having a first length and a plurality of second package contacts having a second length greater than the first length, wherein a respective one of the plurality of first package contacts may be configured to extend into a corresponding one of the plurality of second conductive segments, and wherein a respective one of the plurality of second package contacts may be configured to extend into a corresponding one of the plurality of first conductive segments through a corresponding one of the second spacings; at least one chip coupled to a top surface of the package substrate; and a printed circuit board attached to a bottom surface of the dielectric layer, wherein the printed circuit board may include a plurality of board contacts configured to extend into at least one of the first conductive segments or the second conductive segments.

To more readily understand and put into practice the aspects of the present semiconductor package, particular aspects will now be described by way of examples and not limitations, and with reference to the figures. For the sake of brevity, duplicate descriptions of features and properties may be omitted.

It should be understood that the terms “on”, “under”, “top”, “bottom”, etc., when used in this description are used for convenience and to aid understanding of relative positions or directions, and not intended to limit the orientation of any device, or structure or any part of any device or structure.

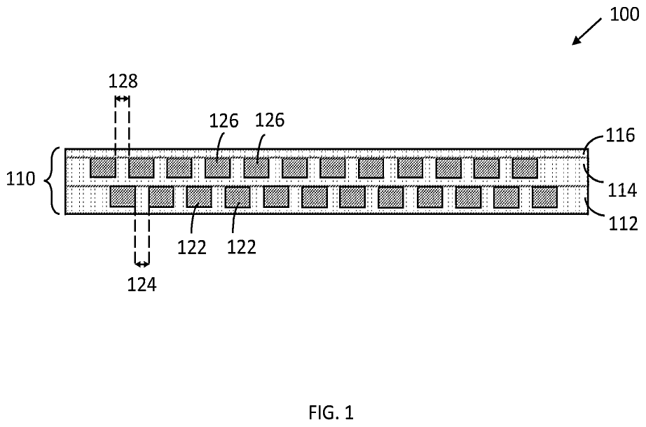

In an aspect shown in FIG. 1, a device 100 of the present disclosure is shown in a cross-sectional view layout, including a dielectric layer 110, a plurality of first conductive segments 122 within the dielectric layer 110 and spaced apart from each other by respective first spacings 124, and a plurality of second conductive segments 126 within the dielectric layer 110 and spaced apart from each other by respective second spacings 128. The plurality of second conductive segments 126 may be over and spaced apart from the plurality of first conductive segments 122 by the dielectric layer 110. A respective one of the first conductive segments 122 may at least partially extend across a corresponding one of the second spacings 128, and a respective one of the second conductive segments 126 may at least partially extend across a corresponding one of the first spacings 124.

According to various aspects of the present disclosure, the plurality of first conductive segments 122 and the plurality of second conductive segments 126 may be arranged in separate levels, and may be offset from each other to provide an electronic interconnect 100, i.e., a high-density interconnect structure/stack 100 with a staggered configuration for device miniaturization.

In various aspects, the respective first conductive segments 122 at least partially extending across the corresponding second spacings 128 may be understood that the respective first conductive segments 122 at least partially overlap, face, or opposite the corresponding second spacings 128. In other words, the first conductive segments 122 may be offset from and alternate with the second conductive segments 126, and may be vertically aligned with the corresponding second spacings 128. In this arrangement, a path from the respective one of the first conductive segments 122 to the corresponding one of the second spacings 128 may be formed, to allow for an electrical coupling/connection from a top end of the dielectric layer 110 to the respective one of the first conductive segments 122 through the corresponding one of the second spacings 128. Similarly, the respective second conductive segments 126 may be vertically aligned with the corresponding first spacings 124, and the respective second conductive segments 126 may at least partially extend across, overlap, face, or opposite the corresponding first spacings 124 to allow for an electrical coupling/connection from a bottom end of the dielectric layer 110 to the respective one of the second conductive segments 126 through the corresponding one of the first spacings 124. Thereby, the first spacings 124 and the second spacings 128 may be better utilized for interconnection and an increased input/output (I/O) density may be achieved.

In various aspects, shapes and/or dimensions of the first conductive segments 122 may be the same as or may be different from shapes and/or dimensions of the second conductive segments 126. In an aspect, the shapes and/or the dimensions of the first conductive segments 122 may be the same as or may be different from each other. In a further aspect, the shapes and/or the dimensions of the second conductive segments 126 may be the same as or may be different from each other. The shapes and/or the dimensions of the first conductive segments 122 and the second conductive segments 126 may be varied according to design choices, as long as the respective first/second conductive segments 122/126 at least partially extend across the corresponding second/first spacings 128/124.

In various aspects, the first spacings 124 may be the same as or may be different from the second spacings 128. In an aspect, the first spacings 124 may be the same as or may be different from each other. In a further aspect, the second spacings 128 may be the same as or may be different from each other. In an example, the second spacings 128 may be equivalent to the first spacings 124, ranging from 100 μm to 800 μm. In another example, the second spacings 128 may be configured to be greater than the first spacings 124. The first spacings 124 and the second spacings 128 may be varied according to design choices, as long as the respective first/second conductive segments 122/126 at least partially extend across the corresponding second/first spacings 128/124.

In various aspects, the plurality of first conductive segments 122 may lie on a first plane, and the plurality of second conductive segments 126 may lie on a second plane parallel to the first plane. In another aspect, the plurality of first conductive segments 122 may lie on different planes parallel to each other. In a further aspect, the plurality of second conductive segments 126 may lie on different planes parallel to each other.

In an aspect, the plurality of first conductive segments 122 and the plurality of second conductive segments 126 may each be arranged in an array including one or more rows and one or more columns. The plurality of first conductive segments 122 may be parallel to the plurality of second conductive segments 126, and may be offset from the plurality of second conductive segments 126 according to various aspects described above.

According to various aspects, the plurality of first conductive segments 122 and the plurality of second conductive segments 126 may be spaced apart from surfaces of the dielectric layer 110. In other words, the first conductive segments 122 and the second conductive segments 126 may be enclosed or buried in the dielectric layer 110, without being exposed from the surfaces of the dielectric layer 110.

The first conductive segments 122 and the second conductive segments 126 may include any suitable conductive material for electrical conduction. In an aspect, the plurality of first conductive segments 122 and the plurality of second conductive segments 126 may include a liquid metal. For example, the plurality of first conductive segments and the plurality of second conductive segments may include at least one of tin, indium, gallium, francium, cesium, or rubidium composites.

The dielectric layer 110 may include a non-conductive layer, e.g., at least one of epoxy polymer, polyimide, polyamide, polyurethane, or polyester. The dielectric layer 110 may enclose and isolate the first conductive segments 122 and the second conductive segments 126.

In an aspect as illustrated in FIG. 1, the dielectric layer 110 may be a composite dielectric layer including a first dielectric layer 112, a second dielectric layer 114 on a top surface of the first dielectric layer 112, and a third dielectric layer 116 on a top surface of the second dielectric layer 114. The plurality of first conductive segments 122 may extend from the top surface of the first dielectric layer 112 into the first dielectric layer 112, and may be spaced apart from a bottom surface of the first dielectric layer 112. The plurality of second conductive segments 126 may extend from the top surface of the second dielectric layer 114 into the second dielectric layer 114 and may be spaced apart from a bottom surface of the second dielectric layer 114. The first dielectric layer 112, the second dielectric layer 114, and the third dielectric layer 116 may include the same or different dielectric material, e.g., at least one of epoxy polymer, polyimide, polyamide, polyurethane, or polyester. In a further aspect, the dielectric layer 110 may be a single uniform layer.

In an example, the first dielectric layer 112 may have a first thickness ranging from 50 μm to 300 μm. In an aspect, the first conductive segments 122 may extend into the first dielectric layer 112 with a first depth ranging from 20% to 90% of the first thickness. In a further example, the second dielectric layer 114 may have a second thickness ranging from 50 μm to 300 μm. In an aspect, the second conductive segments 126 may extend into the second dielectric layer 114 with a second depth ranging from 20% to 90% of the second thickness. In an example, the third dielectric layer 116 may have a third thickness ranging from 20 μm to 100 μm.

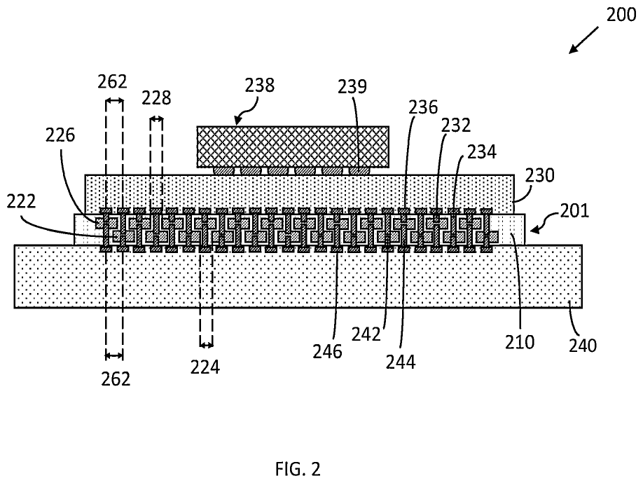

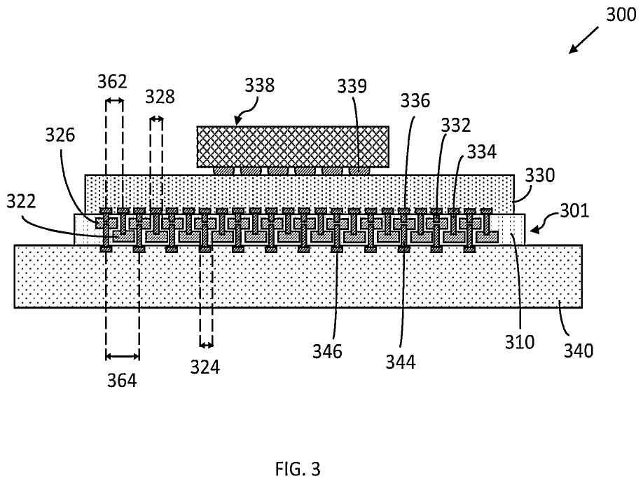

The device 100 with the first conductive segments 122 and the second conductive segments 126 arranged according to various aspects above may provide an electronic interconnect, i.e., an interconnect structure/stack 100, e.g., a liquid metal interconnect, which may be configured to couple a semiconductor package to a printed circuit board as shown in the aspects of FIG. 2 and FIG. 3 below.

According to various aspects of the present disclosure, the device 100 may further include a package substrate (shown in FIG. 2 and FIG. 3 below) on a top surface of the dielectric layer 110. The package substrate may include a plurality of first package contacts having a first length and a plurality of second package contacts having a second length greater than the first length. A respective one of the plurality of first package contacts may be configured to extend into a corresponding one of the plurality of second conductive segments 126, and a respective one of the plurality of second package contacts may be configured to extend into a corresponding one of the plurality of first conductive segments 122 through a corresponding one of the second spacings 128.

According to various aspects of the present disclosure, the device 100 may further include at least one chip (shown in FIG. 2 and FIG. 3 below) coupled to a top surface of the package substrate. The at least one chip may be a silicon device, and may include one or more of a central processing unit (CPU), a graphic processing unit (GPU), a neural processing unit (NPU), a deep learning processor (DLP), a system-on-chip (SOC), a memory device, a field programmable gate array (FGPA), or a transceiver.

The device 100, when assembled with the package substrate and the chips according to various aspects above, may form an electronic package or assembly which may be further attached to a printed circuit board.

According to various aspects of the present disclosure, the device 100 may further include a printed circuit board attached to a bottom surface of the dielectric layer 110, as shown in FIG. 2 and FIG. 3 below. The printed circuit board may include a plurality of board contacts configured to extend into at least one of the first conductive segments 122 or the second conductive segments 126. In other words, the plurality of board contacts may be configured to extend into either the first conductive segments 122 or the second conductive segments 126, or both of the first conductive segments 122 and the second conductive segments 126.

In an aspect, the plurality of board contacts may include a plurality of first board contacts, wherein a respective one of the plurality of first board contacts may be configured to extend into a corresponding one of the plurality of first conductive segments 122. In another aspect, the plurality of board contacts may include a plurality of second board contacts, wherein a respective one of the plurality of second board contacts may be configured to extend into a corresponding one of the plurality of second conductive segments 126 through a corresponding one of the first spacings 124. In a further aspect, the plurality of board contacts may include both the first board contacts and the second board contacts.

FIG. 2 shows a cross-sectional view of a device 200 according to a further aspect of the present disclosure. Many of the aspects of the device 200 are the same or similar to those of the device 100. For the sake of brevity, duplicate descriptions of features and properties are omitted. Accordingly, it will be understood that the descriptions of any feature and/or property relating to FIG. 2 that are the same or similar to a feature and/or property in FIG. 1 will have those descriptions be applicable hereinbelow as well.

In the aspect shown in FIG. 2, a device 200 of the present disclosure is shown in a cross-sectional view layout, including a dielectric layer 210, a plurality of first conductive segments 222 within the dielectric layer 210 and spaced apart from each other by respective first spacings 224, and a plurality of second conductive segments 226 within the dielectric layer 210 and spaced apart from each other by respective second spacings 228. The plurality of second conductive segments 226 may be over and spaced apart from the plurality of first conductive segments 222 by the dielectric layer 210. A respective one of the first conductive segments 222 may at least partially extend across a corresponding one of the second spacings 228, and a respective one of the second conductive segments 226 may at least partially extend across a corresponding one of the first spacings 224.

The plurality of first conductive segments 222 and the plurality of second conductive segments 226 may be arranged in separate levels in the dielectric layer 210, and may be offset from each other to provide a high-density interconnect structure/stack 201 with a staggered configuration for device miniaturization.

According to various aspects of FIG. 2, the device 200 may further include a package substrate 230 on a top surface of the dielectric layer 210. The package substrate 230 may include a plurality of first package contacts 232 having a first length and a plurality of second package contacts 234 having a second length greater than the first length. In an example, the first length may range from 50 μm to 150 μm. In a further example, the second length may range from 150 μm to 300 μm. As shown in FIG. 2, a respective one of the plurality of first package contacts 232 may be configured to extend into a corresponding one of the plurality of second conductive segments 226 from the top surface of the dielectric layer 210, passing through a portion of the dielectric layer 210. A respective one of the plurality of second package contacts 234 may be configured to extend into a corresponding one of the plurality of first conductive segments 222 from the top surface of the dielectric layer 210, passing through a corresponding one of the second spacings 228 and a portion of the dielectric layer 210.

The plurality of first package contacts 232 and the plurality of second package contacts 234 may extend out of the package substrate 230, and may be coupled to a plurality of package contact pads 236 at the bottom surface of the package substrate 230. The first package contacts 232 and the second package contacts 234 may also be referred to as the first package pins 232 and the second package pins 234, respectively.

In an aspect, the plurality of first package contacts 232 may alternate with the plurality of second package contacts 234, such that the respective first package contact 232 with a shorter length may extend into the corresponding second conductive segment 226 which may be closer to the package substrate 230, and the respective second package contact 234 with a greater length may extend into the corresponding first conductive segment 222 which is further from the package substrate 230. Accordingly, the respective first package contact 232 may be electrically coupled to the corresponding second conductive segment 226, and the respective second package contact 234 may be electrically coupled to the corresponding first conductive segment 222.

According to an aspect of FIG. 2, the device 200 may further include at least one chip 238 coupled to a top surface of the package substrate 230, e.g., through solder bumps 239. The at least one chip 238 may be a silicon device, and may include one or more of a central processing unit (CPU), a graphic processing unit (GPU), a neural processing unit (NPU), a deep learning processor (DLP), a system-on-chip (SOC), a memory device, a field programmable gate array (FGPA), or a transceiver.

The interconnect structure 201, when assembled with the package substrate 230 and the chips 238 according to various aspects above, may form an electronic package or assembly which may be further attached to a printed circuit board.

According to various aspects of FIG. 2, the device 200 may further include a printed circuit board (PCB) 240 attached to a bottom surface of the dielectric layer 210. The printed circuit board 240 may include a plurality of board contacts 242, 244 configured to extend into at least one of the first conductive segments 222 or the second conductive segments 226. In other words, each of the first conductive segments 222 and the second conductive segments 226 may be electrically coupled to the corresponding board contact 242, 244 according to the aspects shown in FIG. 2, or in another aspect, either the first conductive segments 222 or the second conductive segments 226 may be electrically coupled to the corresponding board contacts 242, 244 according to the aspects shown in FIG. 3 below.

According to the aspects shown in FIG. 2, the plurality of board contacts may include a plurality of first board contacts 242, wherein a respective one of the plurality of first board contacts 242 may be configured to extend into a corresponding one of the plurality of first conductive segments 222 from the bottom surface of the dielectric layer 210, passing through a portion of the dielectric layer 210. The plurality of board contacts may further include a plurality of second board contacts 244, wherein a respective one of the plurality of second board contacts 244 may be configured to extend into a corresponding one of the plurality of second conductive segments 226 from the bottom surface of the dielectric layer 210, passing through a portion of the dielectric layer 210 and a corresponding one of the first spacings 224. In another aspect, the plurality of board contacts may include only the first board contacts 242, or may include only the second board contacts 244 as shown in the aspects of FIG. 3 below.

In an aspect, the plurality of first board contacts 242 may have a third length, and the plurality of second board contacts 244 may have a fourth length greater than the third length. In an example, the third length may range from 50 μm to 150 μm. In a further example, the fourth length may range from 150 μm to 300 μm.

The plurality of first board contacts 242 and the plurality of second board contacts 244 may extend out of the PCB 240, and may be coupled to a plurality of board contact pads 246 at the top surface of the PCB 240. The first board contacts 242 and the second board contacts 244 may also be referred to as the first board pins 242 and the second board pins 244, respectively.

In an aspect, the plurality of first board contacts 242 may alternate with the plurality of second board contacts 244, such that the respective first board contact 242 with a shorter length may extend into the corresponding first conductive segment 222 which may be closer to the PCB 240, and the respective second board contact 244 with a greater length may extend into the corresponding second conductive segment 226 which is further from the PCB 240. By extending into the first conductive segment 222, the respective first board contact 242 may be electrically coupled to the corresponding first conductive segment 222. By extending into the second conductive segment 226, the respective second board contact 244 may be electrically coupled to the corresponding second conductive segment 226.

According to the aspects above, the one or more chips 238 may be coupled to the PCB 240 through the package substrate 230 and the interconnect structure 201 described above. In an example, the coupling may be provided through the first conductive segments 222, the associated second package contacts 234, and the associated first board contacts 242. In a further example, the coupling may be provided through the second conductive segments 226, the associated first package contacts 232, and the associated second board contacts 244.

According to the aspects of FIG. 2, the PCB 240 may be a high-density interconnect (HDI) Type IV PCB with a smaller interconnect pitch. As shown in FIG. 2, the PCB 240 has a first pitch 262 between the first and the second board contacts 242, 244, which may be similar to the first pitch 262 between the first and the second package contacts 232, 234. The package substrate 230 and the PCB 240 with the smaller first pitch 262 and hence high-density contact pins may be compatible with the interconnect structure 201 which is configured with separate levels of conductive segments 222, 226 in an arrangement to better utilize the spacings between the conductive segments 222, 226.

Similar to the aspects of FIG. 1 described above, the respective first conductive segments 222 at least partially extending across the corresponding second spacings 228 may be understood that the respective first conductive segments 222 at least partially overlap, face, or opposite the corresponding second spacings 228. In other words, the first conductive segments 222 may be offset from and alternate with the second conductive segments 226, and may be vertically aligned with the corresponding second spacings 228. In this arrangement, a path from the respective one of the first conductive segments 222 to the corresponding one of the second spacings 228 may be formed, to allow for an electrical coupling/connection from a top end of the dielectric layer 210 (e.g., from the package substrate 230) to the respective one of the first conductive segments 222 through the corresponding one of the second spacings 228. Similarly, the respective second conductive segments 226 may be vertically aligned with the corresponding first spacings 224, and the respective second conductive segments 226 may at least partially extend across, overlap, face, or opposite the corresponding first spacings 224 to allow for an electrical coupling/connection from a bottom end of the dielectric layer 210 (e.g., from the PCB 240) to the respective one of the second conductive segments 226 through the corresponding one of the first spacings 224. Thereby, the first spacings 224 and the second spacings 228 may be better utilized for interconnection and an increased input/output (I/O) density may be achieved.

Similar to the aspects of FIG. 1, shapes and/or dimensions of the first conductive segments 222 may be the same as or may be different from shapes and/or dimensions of the second conductive segments 226. The shapes and/or the dimensions of the first conductive segments 222 and the second conductive segments 226 may be varied according to design choices, as long as the respective first/second conductive segments 222/226 at least partially extend across the corresponding second/first spacings 228/224.

Similar to the aspects of FIG. 1, the first spacings 224 may be the same as or may be different from the second spacings 228. In an aspect, the first spacings 224 may be the same as or may be different from each other. In a further aspect, the second spacings 228 may be the same as or may be different from each other. In an example, the second spacings 228 may be equivalent to the first spacings 224, ranging from 100 μm to 800 μm. In another example, the second spacings 228 may be configured to be greater than the first spacings 224. The first spacings 224 and the second spacings 228 may be varied according to design choices, as long as the respective first/second conductive segments 222/226 at least partially extend across the corresponding second/first spacings 228/224.

In various aspects, the plurality of first conductive segments 222 may lie on a first plane, and the plurality of second conductive segments 226 may lie on a second plane parallel to the first plane. In another aspect, the plurality of first conductive segments 222 may lie on different planes parallel to each other. In a further aspect, the plurality of second conductive segments 226 may lie on different planes parallel to each other.

In an aspect, the plurality of first conductive segments 222 and the plurality of second conductive segments 226 may each be arranged in an array including one or more rows and one or more columns. The plurality of first conductive segments 222 may be parallel to the plurality of second conductive segments 226, and may be offset from the plurality of second conductive segments 226 according to various aspects described above.

According to various aspects, the plurality of first conductive segments 222 and the plurality of second conductive segments 226 may be spaced apart from surfaces of the dielectric layer 210.

The first conductive segments 222 and the second conductive segments 226 may include any suitable conductive material, e.g., a liquid metal. In an aspect, the plurality of first conductive segments and the plurality of second conductive segments may include at least one of tin, indium, gallium, francium, cesium, or rubidium composites. When the package substrate 230 and the PCB 240 are coupled or assembled with the interconnect structure 201, the package contacts 232, 244 and the board contacts 242, 244 may extend or penetrate into the liquid metal conductive segments 222, 226 in an easy manner.

The dielectric layer 210 may include a non-conductive layer, e.g., at least one of epoxy polymer, polyimide, polyamide, polyurethane, or polyester. The dielectric layer 210 may enclose and isolate the first conductive segments 222 and the second conductive segments 226.

In an aspect as illustrated in FIG. 2, the dielectric layer 210 may be a single uniform layer. In another aspect similar to FIG. 1, the dielectric layer 210 may be a composite dielectric layer including a first dielectric layer, a second dielectric layer on a top surface of the first dielectric layer, and a third dielectric layer on a top surface of the second dielectric layer, similar to the dielectric layer 110 of FIG. 1.

Various aspects of FIG. 2 provide a computing device or electronic package 200 with an interconnect structure 201 (e.g., a liquid metal interconnect) for improved computing performance and device miniaturization.

FIG. 3 shows a cross-sectional view of a device 300 according to a further aspect of the present disclosure.

Many of the aspects of the device 300 are the same or similar to those of the devices 100, 200. For the sake of brevity, duplicate descriptions of features and properties are omitted. Accordingly, it will be understood that the descriptions of any feature and/or property relating to FIG. 3 that are the same or similar to a feature and/or property in FIG. 1 and FIG. 2 will have those descriptions be applicable hereinbelow as well.

In the aspect shown in FIG. 3, a device 300 of the present disclosure is shown in a cross-sectional view layout, including a dielectric layer 310, a plurality of first conductive segments 322 within the dielectric layer 310 and spaced apart from each other by respective first spacings 324, and a plurality of second conductive segments 326 within the dielectric layer 310 and spaced apart from each other by respective second spacings 328. The plurality of second conductive segments 326 may be over and spaced apart from the plurality of first conductive segments 322 by the dielectric layer 310. A respective one of the first conductive segments 322 may at least partially extend across a corresponding one of the second spacings 328, and a respective one of the second conductive segments 326 may at least partially extend across a corresponding one of the first spacings 324. Accordingly, an interconnect structure 301 including the first conductive segments 322 and the second conductive segments 326 may be provided.

Similar to the aspects of FIG. 2, the device 300 may further include a package substrate 330 on a top surface of the dielectric layer 310. The package substrate 330 may include a plurality of first package contacts 332 having a first length and a plurality of second package contacts 334 having a second length greater than the first length. As shown in FIG. 3, a respective one of the plurality of first package contacts 332 may be configured to extend into a corresponding one of the plurality of second conductive segments 326 from the top surface of the dielectric layer 310, passing through a portion of the dielectric layer 310. A respective one of the plurality of second package contacts 334 may be configured to extend into a corresponding one of the plurality of first conductive segments 322 from the top surface of the dielectric layer 310, passing through a corresponding one of the second spacings 328 and a portion of the dielectric layer 310.

The plurality of first package contacts 332 and the plurality of second package contacts 334 may extend out of the package substrate 330, and may be coupled to a plurality of package contact pads 336 at the bottom surface of the package substrate 330. The first package contacts 332 and the second package contacts 334 may also be referred to as the first package pins 332 and the second package pins 334, respectively.

Similar to the aspects of FIG. 2, the plurality of first package contacts 332 may alternate with the plurality of second package contacts 334, such that the respective first package contact 332 with a shorter length may extend into the corresponding second conductive segment 326 which may be closer to the package substrate 330, and the respective second package contact 334 with a greater length may extend into the corresponding first conductive segment 322 which is further from the package substrate 330.

Similar to the aspects of FIG. 2, the device 300 may further include at least one chip 338 coupled to a top surface of the package substrate 330, e.g., through solder bumps 339. The interconnect structure 301, when assembled with the package substrate 330 and the chips 338 according to various aspects above, may form an electronic package or assembly which may be further attached to a printed circuit board.

In the aspects of FIG. 3, the device 300 may further include a printed circuit board (PCB) 340 attached to a bottom surface of the dielectric layer 310. The printed circuit board 340 may include a plurality of board contacts 344, wherein a respective one of the plurality of board contacts 344 may be configured to extend into a corresponding one of the plurality of second conductive segments 326 from the bottom surface of the dielectric layer 310, passing through a portion of the dielectric layer 310 and a corresponding one of the first spacings 324. By extending into the second conductive segment 326, the respective board contact 344 may be electrically coupled to the corresponding second conductive segment 326.

The plurality of board contacts 344 as shown in FIG. 3 may correspond to the plurality of second board contacts 244 of FIG. 2 with a greater length to extend into the corresponding second conductive segments. In an example, the plurality of board contacts 344 may have a length ranging from 150 μm to 300 μm. In another aspect, the plurality of board contacts of FIG. 3 may correspond to the plurality of first board contacts 242 of FIG. 2 with a shorter length (e.g., ranging from 50 μm to 150 μm) configured to extend into the corresponding first conductive segments.

The plurality of board contacts 344 may extend out of the PCB 340, and may be coupled to a plurality of board contact pads 346 at the top surface of the PCB 340. The board contacts 344 may also be referred to as the board pins 344.

According to the aspects of FIG. 3, the PCB 340 may be a Type III PCB with a larger interconnect pitch than the Type IV PCB 240 of FIG. 2. As shown in FIG. 3, the first and the second package contacts 332, 334 are arranged with a first pitch 362, similar to the first pitch 262 of FIG. 2. The PCB 340 may be provided with a second pitch 364 between the board contacts 344, which may be larger than the first pitch 362. The package substrate 330 and the PCB 340 with different pitches 362, 364 and hence contact pins in different densities may still be compatible with the interconnect structure 301 which is configured with separate levels of conductive segments 322, 326 in an arrangement to better utilize the spacings between the conductive segments 322, 326.

Accordingly, the liquid metal interconnect structure 301 may be applied to support cost-effect PCB design e.g., the Type III PCB technology with a larger interconnect pitch, such as 0.65 mm to 1.0 mm, compared to a high-density interconnect (HDI) Type IV PCB technology (shown in FIG. 2) with the same package substrate design and/or pin-map configuration. According to the aspects of FIG. 3, a PCB design configuration with larger contact pad pitch geometry e.g., the Type-III PCB, may be supported with the same package design through the liquid metal interconnect structure 301.

Similar to the aspects described in FIG. 2 above, the one or more chips 338 may be coupled to the PCB 340 through the package substrate 330 and the interconnect structure 301 described above. In the aspect shown in FIG. 3, the coupling may be provided through the second conductive segments 326, the associated first package contacts 332, and the associated board contacts 344. In another aspect where the board contacts 344 correspond to the first board contacts 242 of FIG. 2, the coupling may be provided through the first conductive segments 322, the associated second package contacts 334, and the associated board contacts.

Various aspects of FIG. 3 provide a computing device or electronic package 300 with an interconnect structure 301 (e.g., a liquid metal interconnect) for improved computing performance and device miniaturization.

Various aspects of the device 300, such as the features and properties of the conductive segments and the dielectric layer, may be the same or similar to those described in FIG. 1 and FIG. 2 above, and those descriptions in FIG. 1 and FIG. 2 may be applicable to the device 300 of FIG. 3 as well.

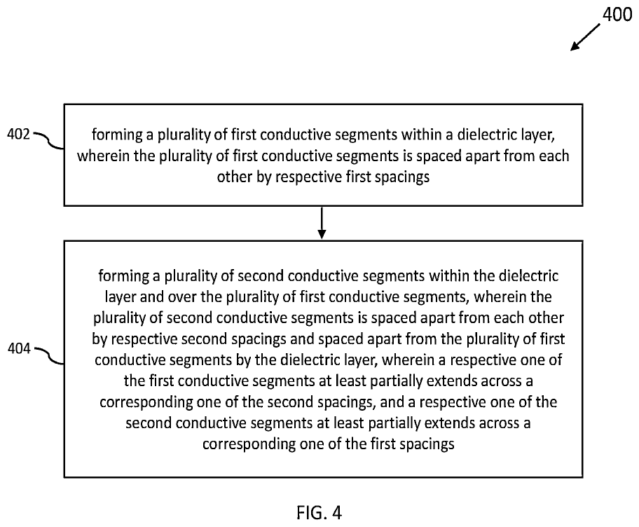

FIG. 4 shows a flowchart 400 illustrating a method of forming a device, such as the device 100, 200, 300 of FIGS. 1-3, according to an aspect of the present disclosure. Various aspects described with reference to FIGS. 1-3 may be similarly applied for the method of FIG. 4.

At 402, a plurality of first conductive segments may be formed within a dielectric layer, wherein the plurality of first conductive segments may be spaced apart from each other by respective first spacings.

At 404, a plurality of second conductive segments may be formed within the dielectric layer and over the plurality of first conductive segments, wherein the plurality of second conductive segments may be spaced apart from each other by respective second spacings and spaced apart from the plurality of first conductive segments by the dielectric layer. A respective one of the first conductive segments may at least partially extend across a corresponding one of the second spacings, and a respective one of the second conductive segments may at least partially extend across a corresponding one of the first spacings

In an aspect, the dielectric layer may be a composite dielectric layer including a first dielectric layer, a second dielectric layer and a third dielectric layer. The method may further include forming the plurality of first conductive segments to extend from a top surface of the first dielectric layer into the first dielectric layer and spaced apart from a bottom surface of the first dielectric layer; forming the second dielectric layer on the top surface of the first dielectric layer, and forming the plurality of second conductive segments to extend from a top surface of the second dielectric layer into the second dielectric layer and spaced apart from a bottom surface of the second dielectric layer; and forming a third dielectric layer on the top surface of the second dielectric layer.

In a further aspect, the method may further include providing a package substrate including a plurality of first package contacts having a first length and a plurality of second package contacts having a second length greater than the first length; and configuring a respective one of the plurality of first package contacts to extend into a corresponding one of the plurality of second conductive segments, and configuring a respective one of the plurality of second package contacts to extend into a corresponding one of the plurality of first conductive segments through a corresponding one of the second spacings, thereby attaching the package substrate to a top surface of the dielectric layer.

According to a further aspect, the method may further include providing a printed circuit board including a plurality of board contacts; and configuring the plurality of board contacts to extend into at least one of the first conductive segments or the second conductive segments, thereby attaching the printed circuit board to a bottom surface of the dielectric layer.

In a further aspect, configuring the plurality of board contacts may further include at least one of: configuring a respective one of a plurality of first board contacts to extend into a corresponding one of the plurality of first conductive segments; or configuring a respective one of a plurality of second board contacts to extend into a corresponding one of the plurality of second conductive segments through a corresponding one of the first spacings.

It will be understood that the operations described above relating to FIG. 4 are not limited to this particular order. Any suitable, modified order of operations may be used.

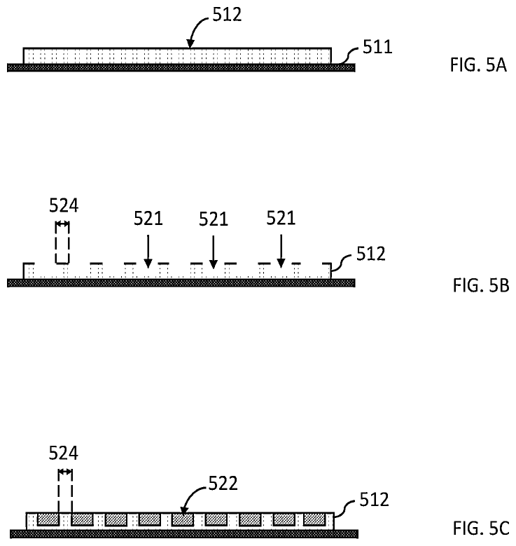

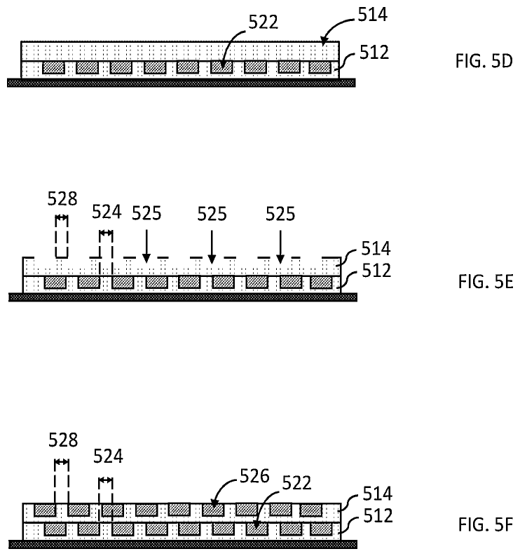

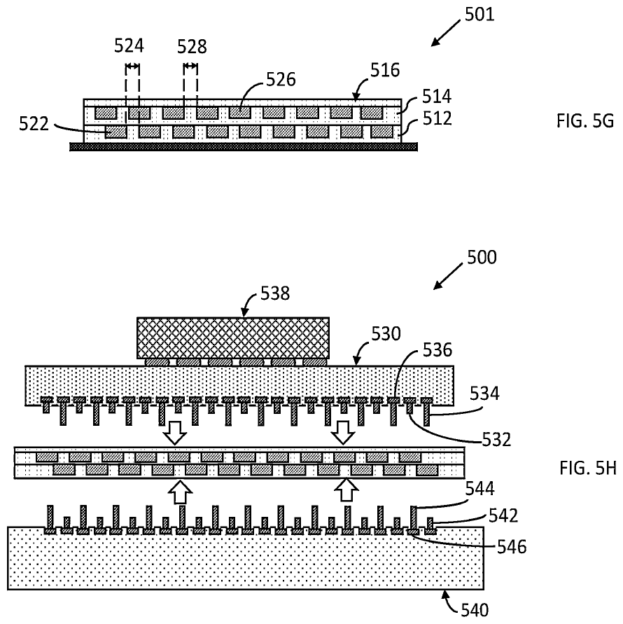

FIGS. 5A through 5H show cross-sectional views directed to an exemplary process flow for a method of making a device (e.g., the device 100, 200, 300) according to an aspect of the present disclosure. Various aspects described with reference to FIGS. 1-3 may be similarly applied for the process flow of FIG. 5A-5H.

In FIG. 5A, a first dielectric layer 512 may be formed, e.g., laminated on a carrier 511, e.g., through a lamination or hot-press process.

In FIG. 5B, a plurality of first openings 521 may be formed in the first dielectric layer 512, e.g., by removing portions of the first dielectric layer 512 through a mechanical drilling, laser etching or chemical etching process. The first openings 521 may extend from a top surface of the first dielectric layer 512 into the first dielectric layer 512, but spaced apart from a bottom surface of the first dielectric layer 512. The plurality of first openings 521 may be spaced apart from each other by respective first spacings 524.

In FIG. 5C, a conductive material, e.g., liquid metal, may be formed or deposited within the plurality of first openings 521 to form a plurality of first conductive segments 522, e.g., through a compression/transfer/injection/printing process. The plurality of first conductive segments 522 may be spaced apart from each other by the respective first spacings 524.

In FIG. 5D, a second dielectric layer 514 may be formed, e.g., laminated on the first dielectric layer 512, e.g., through a lamination or hot-press process. The second dielectric layer 514 may cover a top surface of the first conductive segments 522.

In FIG. 5E, a plurality of second openings 525 may be formed in the second dielectric layer 514, e.g., by removing portions of the second dielectric layer 514 through a mechanical drilling, laser etching or chemical etching process. The second openings 525 may extend from a top surface of the second dielectric layer 514 into the second dielectric layer 514, but spaced apart from a bottom surface of the second dielectric layer 514. The plurality of second openings 525 may be spaced apart from each other by respective second spacings 528. In an aspect as shown in FIG. 5E, a respective one of the second openings 525 may at least partially extend across a corresponding one of the first spacings 524.

In FIG. 5F, a conductive material, e.g., liquid metal, may be formed or deposited within the plurality of second openings 525 to form a plurality of second conductive segments 526, e.g., through a compression/transfer/injection/printing process. The plurality of second conductive segments 526 may be spaced apart from each other by the respective second spacings 528. In the aspect shown in FIG. 5F, a respective one of the first conductive segments 522 may be formed to at least partially extend across a corresponding one of the second spacings 528, and a respective one of the second conductive segments 526 may be formed to at least partially extend across a corresponding one of the first spacings 524.

In FIG. 5G, a third dielectric layer 516 may be formed, e.g., laminated on the second dielectric layer 514, e.g., through a lamination or hot-press process. The third dielectric layer 516 may cover the top surface of the second conductive segments 526.

In the aspect shown in FIG. 5G, an interconnect structure/stack 501 (e.g., a liquid metal interconnect structure/stack 501) similar to the device 100 may be formed, including the first conductive segments 522 and the second conductive segments 526 according to various aspects above.

In FIG. 5H, the interconnect structure/stack 501 may be attached to a package substrate 530 and a PCB 540, e.g., through a thermal compression or curing process.

The package substrate 530 may include a plurality of first package contacts 532 having a first length and a plurality of second package contacts 534 having a second length greater than the first length. A respective one of the plurality of first package contacts 532 may be configured to extend into a corresponding one of the plurality of second conductive segments 526. A respective one of the plurality of second package contacts 534 may be configured to extend into a corresponding one of the plurality of first conductive segments 522, passing through a corresponding one of the second spacings 528. The plurality of first package contacts 532 and the plurality of second package contacts 534 may extend out of the package substrate 530, and may be coupled to a plurality of package contact pads 536 at the bottom surface of the package substrate 530. A chip 538 may be coupled to a top surface of the package substrate 530.

In the aspect shown in FIG. 5H, the PCB 540 may include a plurality of first board contacts 542, wherein a respective one of the plurality of first board contacts 542 may be configured to extend into a corresponding one of the plurality of first conductive segments 522, passing through a portion of the first dielectric layer 512. The PCB 540 may further include a plurality of second board contacts 544, wherein a respective one of the plurality of second board contacts 544 may be configured to extend into a corresponding one of the plurality of second conductive segments 526, passing through a portion of the first dielectric layer 512, a corresponding one of the first spacings 524 and a portion of the second dielectric layer 514. The PCB 540 may be similar to the PCB 240 of FIG. 2. In another aspect, the PCB 540 may include only the first board contacts 542, or may include only the second board contacts 544 similar to the PCB 340 of FIG. 3.

The plurality of first board contacts 542 and the plurality of second board contacts 544 may extend out of the PCB 540, and may be coupled to a plurality of board contact pads 546 at a top surface of the PCB 540.

According to the aspects of FIG. 5H, the package substrate 530 and the chip 538 may be coupled to the interconnect structure 501 to form an electronic package, which may be assembled to the PCB 540. The structure 500 of FIG. 5H may be similar to the device 200 of FIG. 2 above, and accordingly the device 200 may be manufactured according to the processes of FIGS. 5A-5H.

FIGS. 5A-5H above illustrate an exemplary process flow to manufacture a device with an interconnect structure. The operation order described above may be interchangeable to achieve optimum assembly yield and/or throughput time.

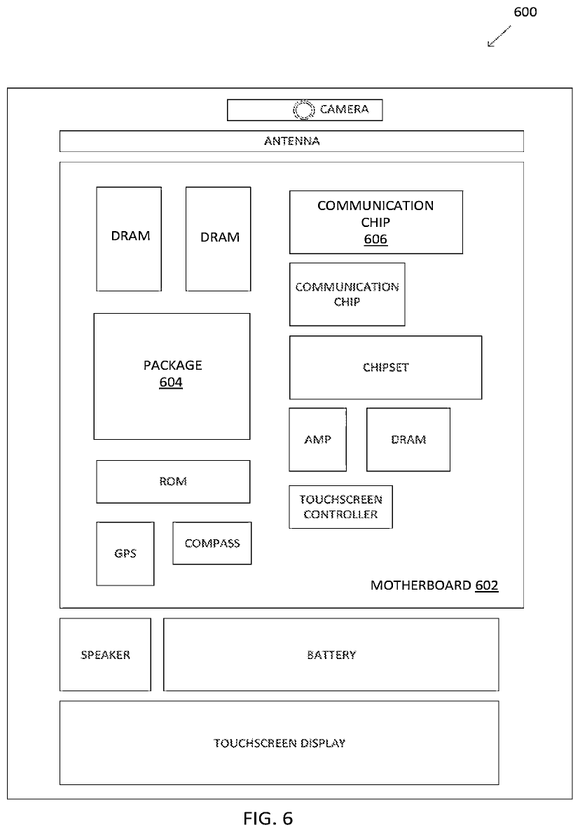

Aspects of the present disclosure may be implemented into a system using any suitable hardware and/or software. FIG. 6 schematically illustrates a computing device 600 that may include a device 100, 200, 300, 500 as described herein, in accordance with some aspects. The computing device 600 may house a board such as a motherboard 602. The motherboard 602 may include several components, including but not limited to a semiconductor package 604, according to the present disclosure, and at least one communication chip 606. The semiconductor package 604, which may include an interconnect structure according to the present disclosure, may be physically and electrically coupled to the motherboard 602. In some implementations, the at least one communication chip 606 may also be physically and electrically coupled to the motherboard 602.

Depending on its applications, the computing device 600 may include other components that may or may not be physically and electrically coupled to the motherboard 602. These other components may include, but are not limited to, volatile memory (e.g., DRAM), non-volatile memory (e.g., ROM), flash memory, a graphics processor, a digital signal processor, a cryptoprocessor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, a camera, and a mass storage device (such as hard disk drive, compact disk (CD), digital versatile disk (DVD), and so forth). In another aspect, the semiconductor package 604 of the computing device 600 may be assembled with an interconnect structure, as described herein.

The communication chip 606 may enable wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some aspects they might not. The communication chip 606 may implement any of several wireless standards or protocols, including but not limited to Institute for Electrical and Electronics Engineers (IEEE) standards including Wi-Fi (IEEE 502.11 family), IEEE 502.16 standards (e.g., IEEE 502.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 502.16 compatible BWA networks are generally referred to as WiMAX networks, an acronym that stands for Worldwide Interoperability for Microwave Access, which is a certification mark for products that pass conformity and interoperability tests for the IEEE 502.16 standards.

The communication chip 606 may also operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 606 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 606 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 606 may operate in accordance with other wireless protocols in other aspects.

The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

In various implementations, the computing device 600 may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In an aspect, the computing device 600 may be a mobile computing device. In further implementations, the computing device 600 may be any other electronic device that processes data.

### EXAMPLES

Example 1 may include a device, including a dielectric layer, a plurality of first conductive segments within the dielectric layer and spaced apart from each other by respective first spacings, and a plurality of second conductive segments within the dielectric layer and spaced apart from each other by respective second spacings. The plurality of second conductive segments may be over and spaced apart from the plurality of first conductive segments by the dielectric layer. A respective one of the first conductive segments may at least partially extend across a corresponding one of the second spacings, and a respective one of the second conductive segments may at least partially extend across a corresponding one of the first spacings

Example 2 may include the subject matter of Example 1, wherein the plurality of first conductive segments and the plurality of second conductive segments may be spaced apart from surfaces of the dielectric layer.

Example 3 may include the subject matter of Example 1 or 2, wherein the plurality of first conductive segments may lie on a first plane, and the plurality of second conductive segments may lie on a second plane parallel to the first plane.

Example 4 may include the subject matter of any one of Example 1 to 3, wherein the plurality of first conductive segments and the plurality of second conductive segments may include a liquid metal.

Example 5 may include the subject matter of any one of Example 1 to 4, wherein the plurality of first conductive segments and the plurality of second conductive segments may include at least one of tin, indium, gallium, francium, cesium, or rubidium composites.

Example 6 may include the subject matter of any one of Example 1 to 5, wherein the dielectric layer may include at least one of epoxy polymer, polyimide, polyamide, polyurethane, or polyester.

Example 7 may include the subject matter of any one of Example 1 to 6, wherein the dielectric layer may be a composite dielectric layer including: a first dielectric layer, wherein the plurality of first conductive segments may extend from a top surface of the first dielectric layer into the first dielectric layer and may be spaced apart from a bottom surface of the first dielectric layer; a second dielectric layer on the top surface of the first dielectric layer, wherein the plurality of second conductive segments may extend from a top surface of the second dielectric layer into the second dielectric layer and may be spaced apart from a bottom surface of the second dielectric layer; and a third dielectric layer on the top surface of the second dielectric layer.

Example 8 may include the subject matter of any one of Example 1 to 7, further including a package substrate on a top surface of the dielectric layer, wherein the package substrate may include a plurality of first package contacts having a first length and a plurality of second package contacts having a second length greater than the first length.

Example 9 may include the subject matter of Example 8, wherein a respective one of the plurality of first package contacts may be configured to extend into a corresponding one of the plurality of second conductive segments, and wherein a respective one of the plurality of second package contacts may be configured to extend into a corresponding one of the plurality of first conductive segments through a corresponding one of the second spacings.

Example 10 may include the subject matter of Example 8 or 9, further including at least one chip coupled to a top surface of the package substrate.

Example 11 may include the subject matter of any one of Example 1 to 10, further including a printed circuit board attached to a bottom surface of the dielectric layer, wherein the printed circuit board may include a plurality of board contacts configured to extend into at least one of the first conductive segments or the second conductive segments.

Example 12 may include the subject matter of Example 11, wherein the plurality of board contacts may include a plurality of first board contacts, wherein a respective one of the plurality of first board contacts may be configured to extend into a corresponding one of the plurality of first conductive segments.

Example 13 may include the subject matter of Example 11 or 12, wherein the plurality of board contacts may include a plurality of second board contacts, wherein a respective one of the plurality of second board contacts may be configured to extend into a corresponding one of the plurality of second conductive segments through a corresponding one of the first spacings.

Example 14 may include a method, the method including forming a plurality of first conductive segments within a dielectric layer, wherein the plurality of first conductive segments may be spaced apart from each other by respective first spacings; and forming a plurality of second conductive segments within the dielectric layer and over the plurality of first conductive segments, wherein the plurality of second conductive segments may be spaced apart from each other by respective second spacings and spaced apart from the plurality of first conductive segments by the dielectric layer; wherein a respective one of the first conductive segments may at least partially extend across a corresponding one of the second spacings, and a respective one of the second conductive segments may at least partially extend across a corresponding one of the first spacings.

Example 15 may include the subject matter of Example 14, wherein the dielectric layer may be a composite dielectric layer include a first dielectric layer, a second dielectric layer and a third dielectric layer, and the method further including: forming the plurality of first conductive segments to extend from a top surface of the first dielectric layer into the first dielectric layer and spaced apart from a bottom surface of the first dielectric layer; forming the second dielectric layer on the top surface of the first dielectric layer, and forming the plurality of second conductive segments to extend from a top surface of the second dielectric layer into the second dielectric layer and spaced apart from a bottom surface of the second dielectric layer; and forming a third dielectric layer on the top surface of the second dielectric layer.

Example 16 may include the subject matter of Example 14 or 15, further including providing a package substrate including a plurality of first package contacts having a first length and a plurality of second package contacts having a second length greater than the first length; and configuring a respective one of the plurality of first package contacts to extend into a corresponding one of the plurality of second conductive segments, and configuring a respective one of the plurality of second package contacts to extend into a corresponding one of the plurality of first conductive segments through a corresponding one of the second spacings, thereby attaching the package substrate to a top surface of the dielectric layer.

Example 17 may include the subject matter of any one of Example 14 to 16, further including providing a printed circuit board including a plurality of board contacts; and configuring the plurality of board contacts to extend into at least one of the first conductive segments or the second conductive segments, thereby attaching the printed circuit board to a bottom surface of the dielectric layer.

Example 18 may include the subject matter of Example 17, wherein configuring the plurality of board contacts may further include at least one of: configuring a respective one of a plurality of first board contacts to extend into a corresponding one of the plurality of first conductive segments; or configuring a respective one of a plurality of second board contacts to extend into a corresponding one of the plurality of second conductive segments through a corresponding one of the first spacings.

Example 19 may include a computing device. The computing device may include an interconnect structure including a dielectric layer, a plurality of first conductive segments within the dielectric layer and spaced apart from each other by respective first spacings, and a plurality of second conductive segments within the dielectric layer and spaced apart from each other by respective second spacings, wherein the plurality of second conductive segments may be over and spaced apart from the plurality of first conductive segments by the dielectric layer, and wherein a respective one of the first conductive segments may at least partially extend across a corresponding one of the second spacings, and a respective one of the second conductive segments may at least partially extend across a corresponding one of the first spacings. The computing device may further include a package substrate on a top surface of the dielectric layer, wherein the package substrate may include a plurality of first package contacts having a first length and a plurality of second package contacts having a second length greater than the first length, wherein a respective one of the plurality of first package contacts may be configured to extend into a corresponding one of the plurality of second conductive segments, and wherein a respective one of the plurality of second package contacts may be configured to extend into a corresponding one of the plurality of first conductive segments through a corresponding one of the second spacings; at least one chip coupled to a top surface of the package substrate; and a printed circuit board attached to a bottom surface of the dielectric layer, wherein the printed circuit board may include a plurality of board contacts configured to extend into at least one of the first conductive segments or the second conductive segments.

Example 20 may include the subject matter of Example 19, wherein the plurality of board contacts may include at least one of: a plurality of first board contacts, wherein a respective one of the plurality of first board contacts may be configured to extend into a corresponding one of the plurality of first conductive segments; or a plurality of second board contacts, wherein a respective one of the plurality of second board contacts may be configured to extend into a corresponding one of the plurality of second conductive segments through a corresponding one of the first spacings.

In a further example, any one or more of examples 1 to 20 may be combined.

These and other advantages and features of the aspects herein disclosed will be apparent through reference to the above description and the accompanying drawings. Furthermore, it is to be understood that the features of the various aspects described herein are not mutually exclusive and can exist in various combinations and permutations.

It will be understood that any property described herein for a specific device may also hold for any device described herein. It will also be understood that any property described herein for a specific method may hold for any of the methods described herein. Furthermore, it will be understood that for any device or method described herein, not necessarily all the components or operations described will be enclosed in the device or method, but only some (but not all) components or operations may be enclosed.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) herein may be understood as electrically coupled or as mechanically coupled, e.g., attached or fixed or attached, or just in contact without any fixation, and it will be understood that both direct coupling or indirect coupling (in other words: coupling without direct contact) may be provided.

While the present disclosure has been particularly shown and described with reference to specific aspects, it should be understood by those skilled in the art that various changes in form and detail may be made therein without departing from the scope of the present disclosure as defined by the appended claims. The scope of the present disclosure is thus indicated by the appended claims and all changes which come within the meaning and range of equivalency of the claims are therefore intended to be embraced.

What is claimed is:

1. A device comprising:
a dielectric layer;
a plurality of first conductive segments within the dielectric layer and spaced apart from each other by respective first spacings;
a plurality of second conductive segments within the dielectric layer and spaced apart from each other by respective second spacings, wherein the plurality of second conductive segments is over and spaced apart from the plurality of first conductive segments by the dielectric layer;
wherein a respective one of the first conductive segments at least partially extends across a corresponding one of the second spacings, and a respective one of the second conductive segments at least partially extends across a corresponding one of the first spacings.

2. The device of claim 1, wherein the plurality of first conductive segments and the plurality of second conductive segments are spaced apart from surfaces of the dielectric layer.

3. The device of claim 1, wherein the plurality of first conductive segments lies on a first plane, and the plurality of second conductive segments lies on a second plane parallel to the first plane.

4. The device of claim 1, wherein the plurality of first conductive segments and the plurality of second conductive segments comprise a liquid metal.

5. The device of claim 1, wherein the plurality of first conductive segments and the plurality of second conductive segments comprise at least one of tin, indium, gallium, francium, cesium, or rubidium composites.

6. The device of claim 1, wherein the dielectric layer comprises at least one of epoxy polymer, polyimide, polyamide, polyurethane, or polyester.

7. The device of claim 1, wherein the dielectric layer is a composite dielectric layer comprising:
a first dielectric layer, wherein the plurality of first conductive segments extends from a top surface of the first dielectric layer into the first dielectric layer and is spaced apart from a bottom surface of the first dielectric layer;
a second dielectric layer on the top surface of the first dielectric layer, wherein the plurality of second conductive segments extends from a top surface of the second dielectric layer into the second dielectric layer and is spaced apart from a bottom surface of the second dielectric layer; and
a third dielectric layer on the top surface of the second dielectric layer.

8. The device of claim 1, further comprising a package substrate on a top surface of the dielectric layer, wherein the package substrate comprises:
a plurality of first package contacts having a first length; and
a plurality of second package contacts having a second length greater than the first length.

9. The device of claim 8, wherein a respective one of the plurality of first package contacts is configured to extend into a corresponding one of the plurality of second conductive segments, and wherein a respective one of the plurality of second package contacts is configured to extend into a corresponding one of the plurality of first conductive segments through a corresponding one of the second spacings.

10. The device of claim 8, further comprising at least one chip coupled to a top surface of the package substrate.

11. The device of claim 1, further comprising a printed circuit board attached to a bottom surface of the dielectric layer, wherein the printed circuit board comprises a plurality of board contacts configured to extend into at least one of the first conductive segments or the second conductive segments.

12. The device of claim 11, wherein the plurality of board contacts comprises a plurality of first board contacts, wherein a respective one of the plurality of first board contacts is configured to extend into a corresponding one of the plurality of first conductive segments.

13. The device of claim 11, wherein the plurality of board contacts comprises a plurality of second board contacts, wherein a respective one of the plurality of second board contacts is configured to extend into a corresponding one of the plurality of second conductive segments through a corresponding one of the first spacings.

14. A method comprising:
forming a plurality of first conductive segments within a dielectric layer, wherein the plurality of first conductive segments is spaced apart from each other by respective first spacings; and
forming a plurality of second conductive segments within the dielectric layer and over the plurality of first conductive segments, wherein the plurality of second conductive segments is spaced apart from each other by respective second spacings and spaced apart from the plurality of first conductive segments by the dielectric layer;
wherein a respective one of the first conductive segments at least partially extends across a corresponding one of the second spacings, and a respective one of the second conductive segments at least partially extends across a corresponding one of the first spacings.

15. The method of claim 14, wherein the dielectric layer is a composite dielectric layer comprising a first dielectric layer, a second dielectric layer and a third dielectric layer, the method further comprising:
forming the plurality of first conductive segments to extend from a top surface of the first dielectric layer into the first dielectric layer and spaced apart from a bottom surface of the first dielectric layer;
forming the second dielectric layer on the top surface of the first dielectric layer, and forming the plurality of second conductive segments to extend from a top surface of the second dielectric layer into the second dielectric layer and spaced apart from a bottom surface of the second dielectric layer; and
forming a third dielectric layer on the top surface of the second dielectric layer.

16. The method of claim 14, further comprising:
providing a package substrate comprising a plurality of first package contacts having a first length and a plurality of second package contacts having a second length greater than the first length;
configuring a respective one of the plurality of first package contacts to extend into a corresponding one of the plurality of second conductive segments, and configuring a respective one of the plurality of second package contacts to extend into a corresponding one of the plurality of first conductive segments through a corresponding one of the second spacings, thereby attaching the package substrate to a top surface of the dielectric layer.

17. The method of claim 14, further comprising:
providing a printed circuit board comprising a plurality of board contacts; and
configuring the plurality of board contacts to extend into at least one of the first conductive segments or the second conductive segments, thereby attaching the printed circuit board to a bottom surface of the dielectric layer.

18. The method of claim 17, wherein configuring the plurality of board contacts further comprises at least one of:
configuring a respective one of a plurality of first board contacts to extend into a corresponding one of the plurality of first conductive segments; or
configuring a respective one of a plurality of second board contacts to extend into a corresponding one of the plurality of second conductive segments through a corresponding one of the first spacings.

19. A computing device comprising:
an interconnect structure comprising a dielectric layer, a plurality of first conductive segments within the dielectric layer and spaced apart from each other by respective first spacings, and a plurality of second conductive segments within the dielectric layer and spaced apart from each other by respective second spacings, wherein the plurality of second conductive segments is over and spaced apart from the plurality of first conductive segments by the dielectric layer, and wherein a respective one of the first conductive segments at least partially extends across a corresponding one of the second spacings, and a respective one of the second conductive segments at least partially extends across a corresponding one of the first spacings;
a package substrate on a top surface of the dielectric layer, wherein the package substrate comprises a plurality of first package contacts having a first length and a plurality of second package contacts having a second length greater than the first length, wherein a respective one of the plurality of first package contacts is configured to extend into a corresponding one of the plurality of second conductive segments, and wherein a respective one of the plurality of second package contacts is configured to extend into a corresponding one of the plurality of first conductive segments through a corresponding one of the second spacings;
at least one chip coupled to a top surface of the package substrate; and
a printed circuit board attached to a bottom surface of the dielectric layer, wherein the printed circuit board comprises a plurality of board contacts configured to extend into at least one of the first conductive segments or the second conductive segments.

20. The computing device of claim 19, wherein the plurality of board contacts comprises at least one of:
a plurality of first board contacts, wherein a respective one of the plurality of first board contacts is configured to extend into a corresponding one of the plurality of first conductive segments; or
a plurality of second board contacts, wherein a respective one of the plurality of second board contacts is configured to extend into a corresponding one of the plurality of second conductive segments through a corresponding one of the first spacings.
